(19) United States
(12) Patent Application Publication
(10) Pub. No.: US 2019/0221741 A1
(43) Pub. Date: Jul. 18, 2019

(54) POLYMER MASK AND MANUFACTURE METHOD OF POLYMER MASK AND APPLIED THEREOF

(71) Applicant: Wuhan China Star Optoelectronics Semiconductor Display Technology Co., Ltd., Wuhan, Hubei (CN)

(72) Inventor: Fan TANG, Wuhan, Hubei (CN)

(21) Appl. No.: 15/579,344

(22) PCT Filed: Sep. 11, 2017
(86) PCT No.: PCT/CN2017/101276

§ 371 Date: Dec. 4, 2017

(30) Foreign Application Priority Data
Aug. 18, 2017 (CN) 201710713991.1

(51) Int. Cl. H01L 51/00; H01L 27/32; H01L 51/56; G03F 7/00; C23C 14/04; C23C 14/24

(52) U.S. Cl. CPC H01L 51/0011; H01L 27/3211; H01L 51/0009; H01L 51/001; H01L 51/0012; H01L 51/5012; H01L 51/56; G03F 7/0015; C23C 14/042; C23C 14/24; H01L 51/003

(57) ABSTRACT

A polymer mask comprises carrier substrate and mask, and sacrificial layer position between mask and carrier substrate. The mask comprises polymer membrane layer and plurality of holes pass through and located on polymer membrane layer, and polymer membrane layer doping magnetic-nanoparticles. The disclosure further provides a manufacture method of polymer mask, comprising steps of. S1, processing sacrificial layer on carrier substrate. S2, coating polymer precursor on sacrificial layer and cured to form original polymer membrane. S3, positioning photo mask on original polymer membrane, and ablating a non-photo mask shielding region on original polymer membrane to form holes by laser scanning to obtain polymer mask precursor. S4, washing and drying polymer mask precursor, and weakening interaction between carrier substrate and mask for obtain polymer mask. The disclosure further provides the polymer mask described above applied to manufacture OLED.

### RELATED APPLICATIONS

The present application is a National Phase of International Application Number PCT/CN2017/101276, filed Sep. 11, 2017, and claims the priority of China Application No. 201710713991.1, filed Aug. 18, 2017.

### FIELD OF THE DISCLOSURE

The disclosure relates to a manufacture method of organic light emitting diode field, and more particularly to a polymer mask, manufacture method of polymer mask and the polymer mask to apply manufacture of OLED.

### BACKGROUND

Organic Light Emitting Diode (OLED) is a flat panel display technology which has great prospects for development. It does not only possess extremely excellent display performance but also properties of self-illumination, simple structure, ultra thin, fast response speed, wide view angle, low power consumption and capability of realizing flexible display, and therefore is considered as “dream display”. Also, performing investments of the OLED is lower than performing investments of the TFT-LCD. It has been favored by respective big display makers and has become the main selection of the third generation display element. Currently, OLED is in a mass production status and a lot of new technology be developed by research so that OLED display must have breakthrough development.

OLED has anode, organic luminescent layer and cathode forming on the substrate in sequentially. While manufacture OLED display, it needs to evaporate each layer of OLED to array substrate. It will use a correspondingly fine metal mask (FMM) for evaporating process, which made the OLED materials evaporate to the design position by holes on the FMM. Specifically, OLED materials become a sublimation type and pass through to the holes on the FMM and deposit on surface of the substrate to form a film by heating OLED materials. Currently, the OLED display of commercially manufactured color display has RGB-OLED display and white-OLED display corresponding with color filter (CF). The RGB-OLED display is widely use to movable display device, and key factor of display resolution is FMM technology.

Traditional FMM is a metal mask which made by invar, and has holes corresponding to pixel regions of pre-evaporation evaporating substrate. It needs expanding net and soldering process after open hole, and FMM needs to accurately align with evaporating substrate. When manufacture of the highly pixel density panel, the requirement of size of hole needs to getting smaller and the density of hole needs to getting higher. Therefore, the requirement of size of the mask needs to be thinner because the shadow effect. It is a big challenge to control TP and CD in expanding net.

Currently, the technology of manufacture original mask is made by PI membrane. In this manufacture, PI membrane pastes to evaporating substrate after be stretched and fixed by fixture, and then opens the holes corresponding to the pixel regions on the evaporating substrate by laser. So that forming PI mask on the original pixel region. There also having some defect. (1) PI membrane pastes to evaporating substrate after be stretched and then opens the holes by laser, these processes probably will damage Ag electrode of evaporating substrate. Also, residue of the ablated PI membrane will pollute surface of ITO while opening holes on PI membrane. (2) It wills having a tension process and then opens holes, so that will decrease the effective area of PI membrane and change the tension. At this time, adjust the tension will cause change to TP, CD of the PI mask. (3) PI membrane is hard to tightly paste the evaporating substrate because the PI membrane don't have magnetic during coating process, it cause big shadow.

### SUMMARY

A technical problem to be solved by the disclosure is to provide a polymer mask and manufacture method of polymer mask and applied thereof. The manufacture method is easily to make a polymer mask has highly pixel density, and it don't need tension structure and processes. Therefore avoids the problem of needs to change tension and change of size mask open after opens holes by laser.

The polymer mask comprises a carrier substrate and a mask. The mask is at positions on the carrier substrate. The sacrificial layer is at position between the mask and the carrier substrate, and the mask further comprises a polymer membrane layer and a plurality of holes pass through and located on the polymer membrane layer, and the polymer membrane layer doping magnetic-nanoparticles.

In an embodiment, thickness of the polymer membrane layer is 5 μm˜50 μm, and the polymer membrane layer is made of material selected from the group consisting of polyimide (PI), polypropylene (PP), polystyrenes (PS), polyethersulfone (PES), graphene (GP) and polyethylene terephthalate (PET).

In an embodiment, thickness of the sacrificial layer is 1 nm˜5 μm, and the sacrificial layer is made of material selected from the group consisting of photosensitive resin, mercapto-silica and trinitrotoluene (TNT).

Furthermore, the disclosure further provides a manufacture method of polymer mask, comprising steps of.

S1, processing a sacrificial layer on carrier substrate.

S2, coating a polymer precursor on the sacrificial layer and cured to form an original polymer membrane, and the polymer precursor doping magnetic-nanoparticles.

S3, positioning a photo mask on the original polymer membrane, and ablating a non-photo mask shielding region on the original polymer membrane to form holes by laser scanning to obtain a polymer mask precursor.

S4, washing and drying the polymer mask precursor, and weakening the interaction between the carrier substrate and the mask to obtain a polymer mask.

In an embodiment, thickness of the polymer membrane layer is 5 μm˜50 μm, and the polymer membrane layer is made of material selected from the group consisting of polyimide (PI), polypropylene (PP), polystyrenes (PS), polyethersulfone (PES), graphene (GP) and polyethylene terephthalate (PET).

In an embodiment, thickness of the sacrificial layer is 1 nm˜5 μm, and the sacrificial layer is made of material selected from the group consisting of photosensitive resin, mercapto-silica and trinitrotoluene (TNT).

In an embodiment, the step (S4) of weakening the interaction between the carrier substrate and the mask which is to irradiate a surface far away the sacrificial layer of the carrier substrate by laser.

Furthermore, the disclosure further provides a manufacture method of OLED, comprising steps of.

Step 1, stacking an anode and a hole transport layer in sequential on a substrate to form a evaporating substrate.

Step 2, forming a red-emitting layer, a green-emitting layer and a blue-emitting layer on the evaporating substrate respectively by vapor deposition.

Step 3, stacking an electron transport layer and a cathode in sequential on the red-emitting layer, the green-emitting layer and the blue-emitting layer.

Wherein step 2 further comprising steps of.

Q1, processing a sacrificial layer on carrier substrate.

Q2, coating a polymer precursor on the sacrificial layer and cured to form an original polymer membrane, and the polymer precursor doping magnetic-nanoparticles.

Q3, positioning a photo mask on the original polymer membrane, and ablating a non-photo mask shielding region on the original polymer membrane to form holes by laser scanning to obtain a polymer mask precursor.

Q4, washing and drying the polymer mask precursor, and weakening the interaction between the carrier substrate and the mask to obtain a polymer mask.

Q5, aligning the polymer mask and the evaporating substrate, and moving a magnetic board of evaporator on a side far away the polymer mask, the mask is absorbed on a surface of the evaporating substrate such that the carrier substrate is peeled off the sacrificial layer.

Q6, evaporating the evaporating substrate, and respectively to form a red-emitting layer, a green-emitting layer and a blue-emitting layer on the evaporating substrate.

In an embodiment, thickness of the original polymer membrane is 5 μm˜50 μm, and the original polymer membrane is made of material selected from the group consisting of polyimide (PI), graphene (GP) and polyethylene terephthalate (PET); and thickness of the sacrificial layer is 1 nm˜5 μm, and the sacrificial layer is made of material selected from the group consisting of photosensitive resin, mercapto-silica and trinitrotoluene (TNT).

In an embodiment, in step Q6, after evaporating one emitting layer, the magnetic board of evaporator be moved away the evaporating substrate and transported the evaporating substrate to another color evaporator-cavity.

The advantages of this present invention.

(1) The present invention is made by a polymer membrane layer and manufacture by laser scan. The region not be shielded by photo mask of the polymer membrane layer is ablated and forming a polymer mask. Comparing to the metal mask of existing technology, this polymer mask could provides highly pixel density efficiency according to accurately manufacture. Also combine technology of the laser scan and the photo mask in the disclosure, on one hand could consistently keep the holes sizes of the mask and the pixel region on pre-evaporate evaporating substrate. It won't be a situation that the holes sizes on the mask are bigger than the pixel region on pre-evaporating evaporating substrate. On the another hand because forming holes process is very soon so that a number of disadvantages are not existence, for example it needs to use laser beam to open holes one by one while manufacture the metal mask so that spend a lot times, and needs to accurately control the moving of laser beam. Therefore this invention could let manufacture method faster and convince.

(2) Comparing to existing technology, the manufacture method of polymer mask in this disclosure without any tension structure and processes. So that solves the problem for needs to change tension and size of mask holes after opens holes by laser.

(3) The polymer membrane layer of the polymer mask is doped the magnetic-nanoparticles in this disclosure. So that the mask could be absorbed by the magnetic board of evaporator and tightly pasted on the evaporating substrate while the polymer mask is applied to manufacture OLED. On one hand, it doesn't need to stretch and fix the polymer membrane layer, on the other hand washing process after forming the holes could avoid pollution of residue produced by ablating on evaporating substrate efficiency.

(4) The polymer membrane layer of the polymer mask in this disclosure which is a single-membrane layer. Therefore, it does not need to consider about risk of curl deformation caused by different of thermal dilation according to different materials of multiple-layers. Therefore, thickness of the signer-layer is thinner than the multiple-layers, and could reduce adverse effect caused by show effect.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 shows a structural schematic view of a polymer mask according to the first embodiment of the disclosure;

FIG. 2 to FIG. 5 show flow chart of manufacture method of the polymer mask according to the first embodiment of the disclosure; and

FIG. 6 to FIG. 20 show flow chart of manufacture method of OLED according to the second embodiment of the disclosure.

### DETAILED DESCRIPTION OF PREFERRED EMBODIMENTS

The specific structural and functional details disclosed herein are only representative and are intended for describing exemplary embodiments of the disclosure. However, the disclosure can be embodied in many forms of substitution, and should not be interpreted as merely limited to the embodiments described herein.

### Embodiment 1

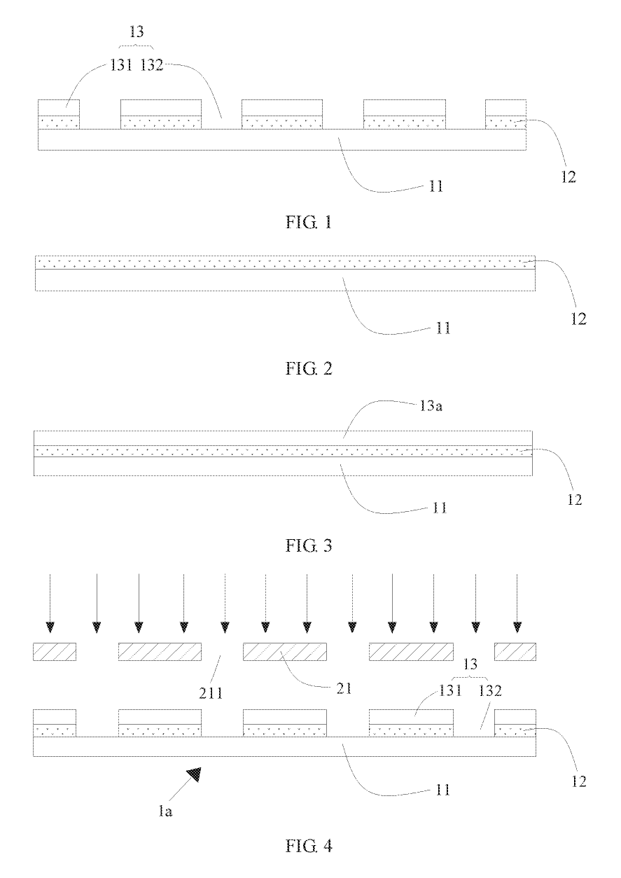

Please refer to FIG. 1, a polymer mask is provided in this embodiment. The polymer mask comprises a carrier substrate 11, a sacrificial layer 12 and a mask 13. The sacrificial layer 12 is at position between the mask 13 and the carrier substrate 11. The mask 13 further comprises a polymer membrane layer 131 and a plurality of holes 132 pass through and arranged on the polymer membrane layer 131, and the polymer membrane layer 131 has magnetic-nanoparticles (not shown).

Specifically, thickness of the polymer membrane layer 131 is 5 μm˜50 μm generally, and the polymer membrane layer 131 is made of material selected from the group consisting of polyimide (PI), polypropylene (PP), polystyrenes (PS), polyethersulfone (PES), graphene (GP) or the modified material and polyethylene terephthalate (PET). Preferably, polymer membrane layer 131 is made by polyimide in this embodiment.

More specifically, thickness of the sacrificial layer 12 is 1 nm˜5 μm generally, and the sacrificial layer is made of material selected from the group consisting of photosensitive resin, mercapto-silica and trinitrotoluene (TNT). The sacrificial layer 12 is used to pill off the carrier substrate 11 from the mask 13 while using the polymer mask, so that it is not limited position of the sacrificial layer 12.

The disclosure will be further described in detail of the manufacture method of polymer mask with reference to accompanying drawings and preferred embodiments as follows.

In this embodiment, the manufacture method of polymer mask as following steps.

Step 1, processing a sacrificial layer 12 on a carrier substrate 11, shown as FIG. 2.

Specifically, the carrier substrate 11 could be transparent hard substrate such as glass substrate, it is not limited thereto.

The thickness of the sacrificial layer 12 is 1 nm˜5 μm generally, and the sacrificial layer is made of material selected from the group consisting of photosensitive resin, mercapto-silica and trinitrotoluene (TNT).

Step 2, coating a polymer precursor on the sacrificial layer 12 and cured to form an original polymer membrane 13a, shown as FIG. 3.

To provide a polymer membrane layer contains magnetic, the polymer precursor evenly doping magnetic-nanoparticles. The magnetic-nanoparticles are evenly disposed in the original polymer membrane 13a while the polymer precursor is cured to form an original polymer membrane.

Generally, thickness of the original polymer membrane 13a is 5 μm˜50 μm, and the original polymer membrane 13a is made of material selected from the group consisting of polyimide (PI), polypropylene (PP), polystyrenes (PS), polyethersulfone (PES), graphene (GP) or the modified material and polyethylene terephthalate (PET). Preferably, original polymer membrane 13a is made by polyimide in this embodiment.

In this embodiment, the polymer precursor is formed to the original polymer membrane 13a by bake process, preferably.

Step 3, positioning a photo mask 21 on the original polymer membrane, and ablating a non-photo mask shielding region on the original polymer membrane to form holes by laser scanning to obtain a polymer mask precursor 1a, shown as FIG. 4.

Specifically, the original polymer membrane formed a polymer membrane layer 131 and a plurality of holes 132 pass through and arranged on the polymer membrane layer 131 by laser ablating, so that to form the mask 13. Shown as FIG. 4, the arrow to be incident direction of laser.

It is worth mentioning that, in this embodiment the incident holes 211 of the photo mask 21 are corresponding to the pre-made holes 132 of the polymer mask, which is according to pixel region of evaporating substrate, and the evaporating substrate is applied to the polymer mask. Therefore, if it needs to evaporate any size of pixel region, here could choose a photo mask 21 has equal to or larger size incident holes 211.

Step 4, washing and drying the polymer mask precursor 1a, and then weakening the interaction between the carrier substrate 11 and the mask 13 to obtain a polymer mask, shown as FIG. 1.

After forming the holes 132, residue produced by ablation will absorbed on surface of the carrier substrate 11. So that washing process could efficiency avoid a pollution of residue during using the polymer mask.

Preferably, weakening the interaction between the carrier substrate 11 and the mask 13 by laser irradiating a surface far away the sacrificial layer 12 of the carrier substrate 11. Shown as FIG. 5, the arrow to be incident direction of laser.

### Embodiment 2

A manufacture method of OLED in this embodiment, which includes a polymer mask provided by embodiment 1. The manufacture method of OLED comprising steps of.

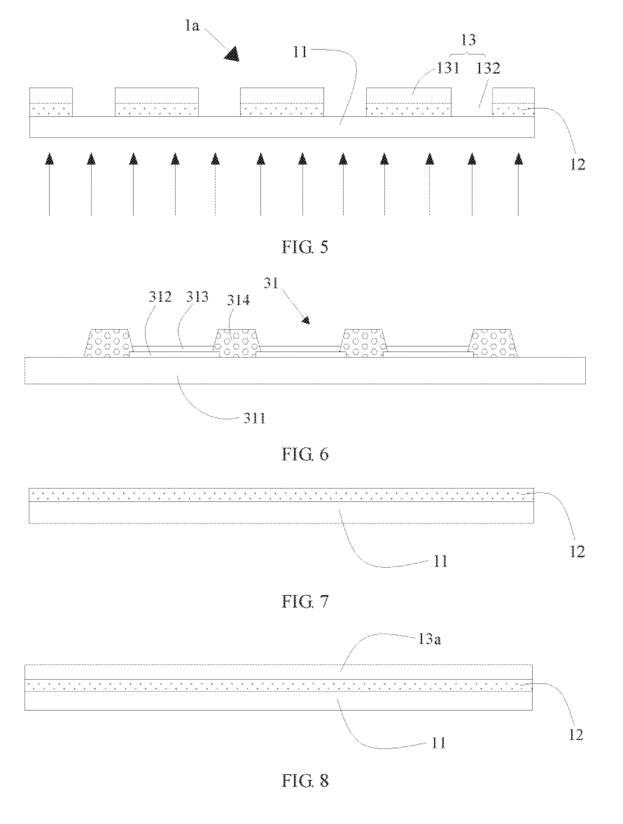

Step 1, stacking an anode 312 and a hole transport layer 313 in sequential on a substrate 311 to form a evaporating substrate 31, shown as FIG. 6.

Preferably, arranging a pixel definition layer 314 between the different pixel regions for manufacturing difference-emitting layers easily.

The manufacture method of the evaporating substrate 31 is refer to existing technology, here is not described again.

Step 2, forming a red-emitting layer 321, a green-emitting layer 322 and a blue-emitting layer 323 on the evaporating substrate 31 respectively by vapor deposition.

Specifically, the step 2 comprising following steps.

Q1, processing a sacrificial layer 12 on a carrier substrate 11, shown as FIG. 7.

Q2, coating a polymer precursor on the sacrificial layer 12 and cured to form an original polymer membrane 13a, shown as FIG. 8.

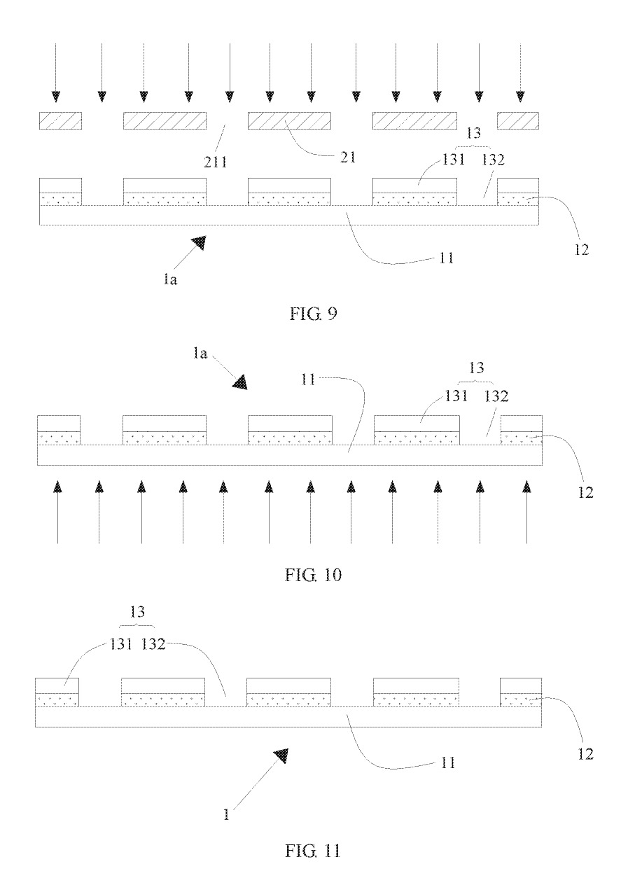

Q3, positioning a photo mask 21 on the original polymer membrane 13a, and ablating a non-photo mask shielding region on the original polymer membrane 13a to form holes 132 by laser scanning for forming mask 13. Therefore obtain a polymer mask precursor. Shown as FIG. 9.

Q4, washing and drying the polymer mask precursor, and then weakening the interaction between the carrier substrate 11 and the mask 13 to obtain a polymer mask 1, shown as FIG. 10 and FIG. 11.

The steps Q1 to Q4 and FIG. 7 to FIG. 10 are respectively corresponding to the steps S1 to S4 and FIG. 2 to FIG. 5 of embodiment 1. Here is not described again.

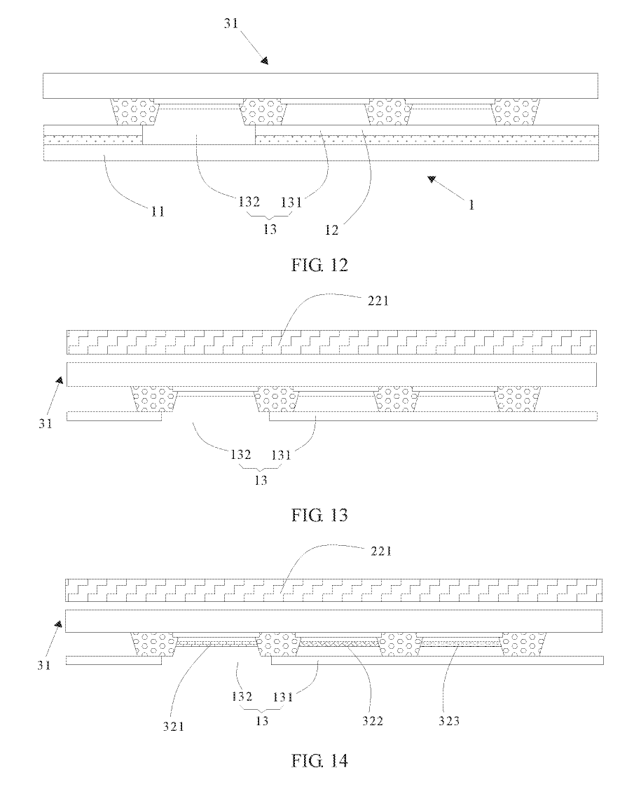

Q5, aligning and pasting the polymer mask 1 and the evaporating substrate 31, and moving a magnetic board 221 of evaporator to a side of evaporating substrate 3 which is far away the polymer mask 1, the mask 13 is absorbed on a surface of the evaporating substrate 31 such that the carrier substrate 11 is peeled off the sacrificial layer 12. Shown as FIG. 12 and FIG. 13.

Q6, evaporating the evaporating substrate 31, and respectively to form a red-emitting layer 321, a green-emitting layer 322 and a blue-emitting layer 323 on the evaporating substrate 31. Shown as FIG. 14.

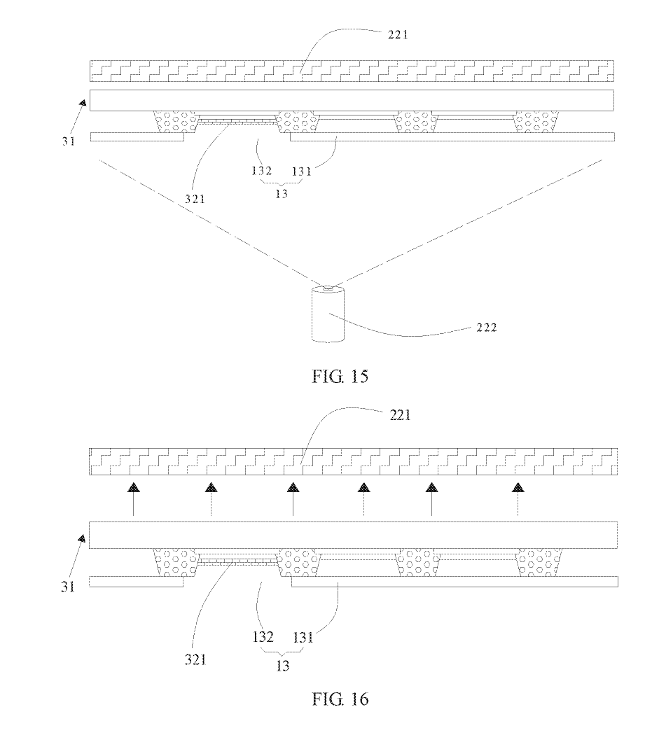

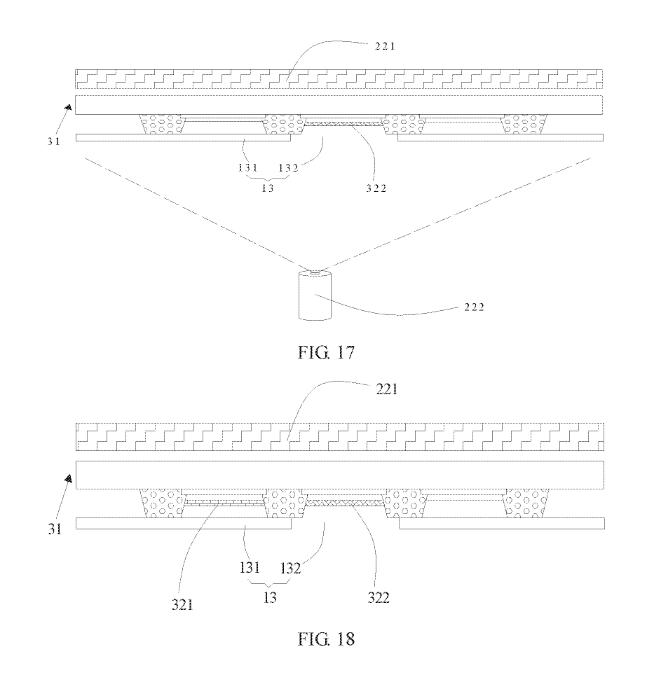

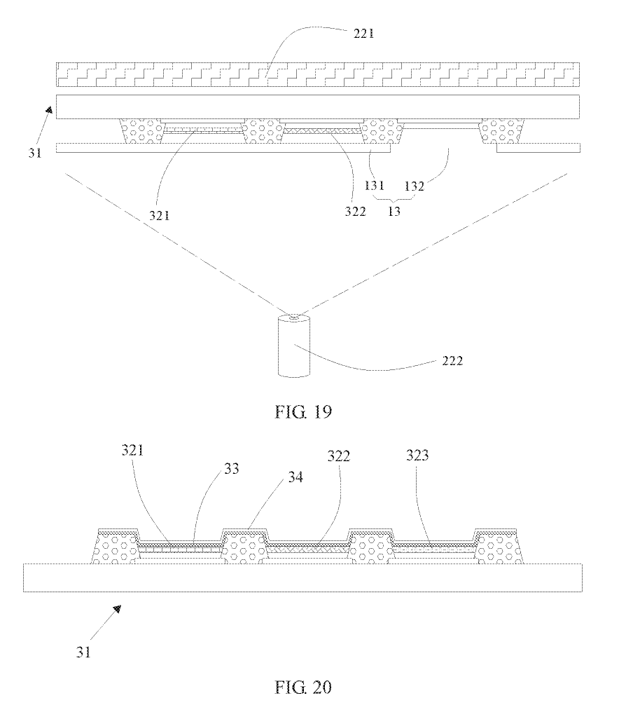

Specifically, in the evaporation process, when finished one color of emitting layer by evaporation, the magnetic board 221 of evaporator will be moved away the evaporating substrate 31, and the moving the evaporating substrate 31 to the correspondingly evaporator-cavity of another color. In this embodiment, if manufacture the red-emitting layer 321 at first, it will aligns the holes 132 to a pixel region which is corresponding to the red-emitting layer 321 when aligns and pastes the polymer mask 1 and the evaporating substrate 31. And pixel regions which are corresponding to the green-emitting layer 322 and the blue-emitting layer 323 are both shielded by polymer membrane layer. At this time, turn on the evaporation source 222 of evaporator and forming red-emitting layer 321 on the correspondingly pixel region, shown as FIG. 15 and FIG. 16. And then manufacture the green-emitting layer 322, it needs to move the magnetic board 221 of evaporator away the evaporating substrate 31, and transports the evaporating substrate 31 for aligning the holes 132 to a pixel region which is corresponding to the green-emitting layer 322, and forming green-emitting layer 322 on the correspondingly pixel region, shown as FIG. 17 and FIG. 18. Finally, manufacture the blue-emitting layer 323 as same as described above, shown as FIG. 19. Therefore, it obtains multiple emitting layers shown as FIG. 14.

It is worth mentioning that, it needs to use different correspondingly mask 13 while manufacture for different color-emitting layers. It is said that after one color emitting layer is be finished, and needs to change mask 13 which corresponding to the finished color emitting layer to another mask 13 corresponding to the pre-manufacture color-emitting layer during transports the evaporating substrate 31. And position and size of the holes 132 of mask 13 will be changed according to requirement of different color-emitting layer.

Step 3, stacking an electron transport layer 33 and a cathode 34 in sequential on the red-emitting layer 321, the green-emitting layer 322 and the blue-emitting layer 323 for obtain an OLED. Shown as FIG. 20.

The manufacture method of electron transport layer 33 and cathode 34 are refer to existing technology, here is not described again.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A polymer mask, comprising
a carrier substrate, and
a mask at positions on the carrier substrate;
wherein a sacrificial layer is at position between the mask and the carrier substrate, and the mask further comprises a polymer membrane layer and a plurality of holes pass through and located on the polymer membrane layer, and the polymer membrane layer doping magnetic-nanoparticles.

2. The polymer mask according to claim 1, wherein thickness of the polymer membrane layer is 5 nm˜50 μm, and the polymer membrane layer is made of material selected from the group consisting of polyimide (PI), polypropylene (PP), polystyrenes (PS), polyethersulfone (PES), graphene (GP) and polyethylene terephthalate (PET).

3. The polymer mask according to claim 1, wherein thickness of the sacrificial layer is 1 nm˜5 μm, and the sacrificial layer is made of material selected from the group consisting of photosensitive resin, mercapto-silica and trinitrotoluene (TNT).

4. The polymer mask according to claim 2, wherein thickness of the sacrificial layer is 1 nm˜5 μm, and the sacrificial layer is made of material selected from the group consisting of photosensitive resin, mercapto-silica and trinitrotoluene (TNT).

5. A manufacture method of polymer mask, comprising steps of:
S1, processing a sacrificial layer on a carrier substrate;
S2, coating a polymer precursor on the sacrificial layer and cured to form an original polymer membrane, and the polymer precursor doping magnetic-nanoparticles;
S3, positioning a photo mask on the original polymer membrane, and ablating a non-photo mask shielding region on the original polymer membrane to form holes by laser scanning for obtains a polymer mask precursor; and
S4, washing and drying the polymer mask precursor, and weakening the interaction between the carrier substrate and the mask to obtain a polymer mask.

6. The manufacture method of polymer mask according to claim 5, wherein thickness of the original polymer membrane is 5 μm˜15 μm, and the original polymer membrane is made of material selected from the group consisting of polyimide (PI), polypropylene (PP), polystyrenes (PS), polyethersulfone (PES), graphene (GP) and polyethylene terephthalate (PET).

7. The manufacture method of polymer mask according to claim 5, wherein thickness of the sacrificial layer is 1 nm˜5 μm, and the sacrificial layer is made of material selected from the group consisting of photosensitive resin, mercapto-silica and trinitrotoluene (TNT).

8. The manufacture method of polymer mask according to claim 5, wherein the step (S4) of weakening the interaction between the carrier substrate and the mask which is to irradiate a surface far away the sacrificial layer of the carrier substrate by laser.

9. The manufacture method of polymer mask according to claim 7, wherein the step (S4) of weakening the interaction between the carrier substrate and the mask which is to irradiate a surface far away the sacrificial layer of the carrier substrate by laser.

10. A manufacture method of OLED, comprising steps of:
step 1, stacking an anode and a hole transport layer in sequential on a substrate to form a evaporating substrate:
step 2, forming a red-emitting layer, a green-emitting layer and a blue-emitting layer on the evaporating substrate respectively by vapor deposition;
step 3, stacking an electron transport layer and a cathode in sequential on the red-emitting layer, the green-emitting layer and the blue-emitting layer;
wherein step 2 further comprising steps of:
Q1, processing a sacrificial layer on a carrier substrate:
Q2, coating a polymer precursor on the sacrificial layer and cured to form an original polymer membrane, and the polymer precursor doping magnetic-nanoparticles;
Q3, positioning a photo mask on the original polymer membrane, and ablating a non-photo mask shielding region on the original polymer membrane to form holes by laser scanning to obtain a polymer mask precursor;
Q4, washing and drying the polymer mask precursor, and weakening the interaction between the carrier substrate and the mask to obtain a polymer mask;
Q5, aligning the polymer mask and the evaporating substrate, and moving a magnetic board of evaporator on a side far away the polymer mask, the mask is absorbed on a surface of the evaporating substrate such that the carrier substrate is peeled off the sacrificial layer; and
Q6, evaporating the evaporating substrate, and respectively form a red-emitting layer, a green-emitting layer and a blue-emitting layer on the evaporating substrate.

11. The manufacture method of OLED according to claim 10, wherein thickness of the original polymer membrane is 5 μm˜50 μm, and the original polymer membrane is made of material selected from the group consisting of polyimide (PI), graphene (GP) and polyethylene terephthalate (PET);
wherein thickness of the sacrificial layer is 1 nm˜5 μm, and the sacrificial layer is made of material selected from the group consisting of photosensitive resin, mercapto-silica and trinitrotoluene (TNT).

12. The manufacture method of OLED according to claim 10, wherein in step Q6, after evaporating one emitting layer, the magnetic board of evaporator be moved away the evaporating substrate and transported the evaporating substrate to another color evaporator-cavity.

13. The manufacture method of OLED according to claim 11, wherein in step Q6, after evaporating one emitting layer, the magnetic board of evaporator be moved away the evaporating substrate and transported the evaporating substrate to another color evaporator-cavity.
